(19) United States
(12) Patent Application Publication
(10) Pub. No.: US 2025/0389488 A1
(43) Pub. Date: Dec. 25, 2025

(54) In-Row Heat Exchangers, and Related Systems and Methods

(71) Applicant: CoolIT Systems, Inc., Calgary (CA)

(72) Inventors: Stefan Tuineag, Calgary (CA); Seyed Kamaleddin Mostafavi Yazdi, Calgary (CA)

(21) Appl. No.: 19/242,831

(22) Filed: Jun. 18, 2025

Related U.S. Application Data
(60) Provisional application No. 63/661,783, filed on Jun. 19, 2024.

(51) Int. Cl. F28D 7/16

(52) U.S. Cl. CPC F28D 7/163

(57) ABSTRACT

Coolant distribution units have an enclosure defining an inlet face and an outlet face. A V-shaped coil is positioned in the enclosure between the inlet face and the outlet face. The V-shaped coil defines an apex and a pair of trailing edges positioned downstream of the apex. The apex is positioned between the trailing edges and the inlet face of the enclosure. The trailing edges are positioned between the apex and the outlet face of the enclosure. An array of fans is configured to draw air through the V-shaped coil and to exhaust the air from the enclosure. Such Coolant distribution units also include a hot-coolant inlet and the V-shaped coil is configured to transfer heat from the coolant received at the hot-coolant inlet to the air drawn through the V-shaped coil.

### CROSS-REFERENCE TO RELATED APPLICATIONS

This non-provisional patent application claims benefit of and priority from provisional U.S. Patent Application No. 63/661,783, filed Jun. 19, 2025, the contents of which are hereby incorporated in their entirety as if fully set forth herein, for all purposes.

This application pertains to concepts disclosed in U.S. Pat. No. 9,496,200, U.S. Patent Application Publication No. 2015/0083368, and U.S. Published Patent Application No. 2023/0240053. Each of the foregoing references is hereby incorporated by reference in its entirety as if fully set forth herein, for all purposes.

### FIELD

This application and the subject matter disclosed herein (collectively referred to as the “disclosure”), generally concern liquid-based heat-transfer systems. More particularly, but not exclusively, this disclosure pertains to liquid-cooling systems for data centers.

### BACKGROUND INFORMATION

The innovations and related subject matter disclosed herein (collectively referred to as the “disclosure”) concern systems configured to transfer heat from one fluid to another fluid, and more particularly, but not exclusively, to systems having a modular configuration. Some examples of such systems are described in relation to cooling electronic components, though the disclosed innovations may be used in a variety of other heat-transfer applications.

New generations of electronic components, such as, for example, memory components, microprocessors, graphics processors, application specific integrated circuits (ASICs), hard drives, and power electronics semiconductor devices, produce increasing amounts of heat when operating. In addition, electronic devices, such as, for example, servers, computers, game consoles, power electronics, communications and other networking devices, batteries, and so on, arrange electronic components in close proximity with each other. If the heat generated by operating such components is not removed from such devices at a sufficient rate, the components can overheat, decreasing their performance, reliability, or both, and in some cases such overheating can result in outright component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active” heat sinks.

Liquid cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, Q in, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, Q′out, from the remote radiator to another medium (e.g., air or facility water passing through the remote radiator), and (4) returning cooled liquid to the heat exchanger (or heat sink). Many heat exchangers for removing heat generated by such components have been proposed. As but one example, device-to-liquid heat exchangers have been proposed, as for example in U.S. patent application Ser. No. 12/189,476 and related patent applications, and in other patent applications (e.g., U.S. Patent Application No. 63/635,593, filed Apr. 17, 2024, U.S. Patent Application No. 61/794,698, filed Mar. 15, 2013). Each of the foregoing disclosures is hereby incorporated by reference as fully as if recited herein in its entirety, for all purposes.

U.S. Patent Application No. 61/794,698, filed Mar. 15, 2013,, disclosed a rack of servers having a coolant loop that circulated coolant through a plurality of a rack-mounted servers and a liquid-to-air heat exchanger (sometimes referred to in the art as a “radiator” or an “air heat exchange module”) mounted atop the rack containing the servers. The radiator was a cross-flow radiator oriented parallel to the floor and rejected heat from the working fluid used to cool the server components to a stream of relatively cooler air passing orthogonally (vertically) through the radiator. An axial fan located above the radiator delivered about 3500 cubic feet of air per minute (cfm) through the radiator. A duct (sometimes referred to in the art as a “chimney”) rested atop the rack to direct air from a server room, through the radiator and into an existing HVAC system in the ceiling.

IBM also previously disclosed several liquid-based cooling systems that uniformly relied on cool facility liquid to receive heat generated during operation of various electronic components. See, M.J. Ellsworth, et al., The Evolution of Water Cooling for IPB Larger Server Systems: Back to the Future, IEEE Publication (2008).

Nevertheless, conventional data centers have heretofore largely relied on air-cooling of electronic components, without any liquid cooling. Such air-cooling systems have typically provided conditioned (e.g., cooled) air throughout the data center. As cloud-based and other services grow, the number of networked computers and computing environments, including servers, has substantially increased and is expected to continue to grow.

In general, heat dissipating components spaced from each other (e.g., a lower heat density) can be more easily cooled than the same components placed in close relation to each other (e.g., a higher heat density). Consequently, data centers have also compensated for increased power dissipation (corresponding to increased server performance) by increasing spacing between adjacent servers. Nonetheless, relatively larger spacing between adjacent servers reduces the number of servers in (and thus the computational capacity of) the data center compared to relatively smaller spacing between adjacent servers.

As used herein, the term “server” generally refers to a computing device connected to a computing network and running software configured to receive requests (e.g., a request to access or to store a file, a request to provide computing resources, a request to connect to another client) from client computing devices also connected to the computing network. Such client computing devices can take the form of traditional personal computers, tablets, smartphones, smart watches, as well as any of a variety of known or hereafter developed smart devices, including but not limited to devices within the so-called “internet of things.”

The term “data center” loosely refers to a physical location housing one or more servers. In some instances, a data center can simply comprise an unobtrusive corner in a small office. In other instances, a data center can comprise several large, warehouse-sized buildings enclosing tens (or hundreds) of thousands of square feet and housing thousands of servers.

### SUMMARY

In some respects, concepts disclosed herein generally concern systems, methods, and devices to remove excess heat from servers and heat-generating components within such servers. More particularly, but not exclusively, some disclosed concepts pertain to liquid-cooling systems that can be retrofitted to existing data centers that have previously relied on air-cooling, and related components and methods. In other respects, some disclosed concepts pertain to liquid-cooling systems that can be installed in new data centers that use air for cooling heat generating components, and related components and methods. As but one example, some disclosed concepts pertain to air-cooled heat exchangers that facilitate heat transfer from a relatively warmer liquid received from a plurality of servers to relatively cooler air supplied by a data center, cooling the liquid as it passes through the heat exchanger and before it returns to the plurality of servers to absorb additional waste heat generated by the servers.

According to an aspect, disclosed coolant distribution units include an enclosure defining an inlet face and an outlet face. A V-shaped coil is positioned in the enclosure between the inlet face and the outlet face. The V-shaped coil defines an apex and a pair of trailing edges positioned downstream of the apex, and the apex is positioned between the trailing edges and the inlet face of the enclosure. The trailing edges are positioned between the apex and the outlet face of the enclosure. An array of fans is configured to draw air through the V-shaped coil and to exhaust the air from the enclosure. Such coolant distribution units also have a hot-coolant inlet, and the V-shaped coil is configured to transfer heat from the coolant received at the hot-coolant inlet to the air drawn through the V-shaped coil.

In some embodiments, the coolant distribution unit also has a selected one or more of a filter, a pipe, a pump, and an accumulator positioned between the apex of the V-shaped coil and the inlet face of the enclosure.

In some embodiments, the coolant distribution unit also has a cool-coolant outlet and an arrangement of plumbing configured to convey coolant from the V-shaped coil to the cool-coolant outlet after the coolant has passed through the V-shaped coil.

The array of fans can include a vertical array of fans. For example, the vertical array of fans can be a first vertical array of fans and the coolant distribution unit can also have a second vertical array of fans positioned laterally adjacent the first vertical array of fans.

In some embodiments, a vertical array of fans can include a plurality of fans, each having an inlet. The plurality of fan inlets can be substantially coplanar with each other. In some embodiments, the plurality of fan inlets is positioned between the apex and the trailing edges of the V-shaped coil.

According to another aspect, in-row coolant distribution units have a cabinet and a V-shaped coil. The cabinet defines a first major face and a second major face. The V-shaped coil is positioned in the cabinet between the first major face and the second major face. The V-shaped coil has an apex and a corresponding pair of trailing edges positioned laterally outward of the apex. The V-shaped coil also defines a respective heat-transfer region between the apex and each of the pair of trailing edges. The in-row coolant distribution unit also has a liquid inlet and a vertical coil manifold adjacent the apex of the V-shaped coil. The vertical coil manifold is coupled with the liquid inlet and configured to distribute a liquid received through the inlet vertically along the V-shaped coil to each respective heat-transfer region between the apex and each of the pair of trailing edges. An array of fans is configured to draw air through each respective heat-transfer region between the apex and each of the pair of trailing edges and to exhaust the air from the cabinet after the air passes through the V-shaped coil.

In some embodiments, each fan in the array of fans has an inlet face, and the inlet face of at least one fan in the array of fans is positioned between a plane defined by the trailing edges of the V-shaped coil and the apex of the V-shaped coil.

Some in-row coolant distribution units also have a liquid outlet and an arrangement of plumbing configured to collect the liquid vertically distributed along the V-shaped coil after the liquid has passed through each respective heat-transfer region of the V-shaped coil. The arrangement of plumbing can be configured to convey the collected liquid to the liquid outlet.

Some in-row coolant distribution units also have an accumulator positioned between the apex of the V-shaped coil and the first major face of the cabinet.

In some embodiments, the array of fans includes a vertical array of fans. The vertical array of fans can be a first vertical array of fans and the coolant distribution unit can also have a second vertical array of fans positioned laterally adjacent the first vertical array of fans.

The vertical coil manifold can include a first vertical manifold configured to distribute the liquid along one of the pair of heat transfer regions. In some embodiments, the vertical coil manifold also has a second vertical manifold configured to distribute the liquid along the other one of the pair of heat transfer regions.

Some in-row coolant distribution units also have a coupler configured to recombine a flow of liquid from one of the pair of heat transfer regions with a flow of liquid from the other one of the pair of heat transfer regions.

Some in-row coolant distribution units also have at least one pump configured to pump the liquid after the liquid passes through the V-shaped coil.

Some in-row coolant distribution units also have at least one pump configured to pump the liquid before the liquid passes through the V-shaped coil.

In some embodiments, the array of fans can also be configured to draw air through the first major face of the cabinet before the air passes through each respective heat-transfer region of the V-shaped coil.

In some embodiments, the array of fans can also be configured configured to exhaust the air through the second major face of the cabinet.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 illustrates a closed liquid cooling loop.

FIG. 2 shows an isometric view from in front and to the side of an inlet-face of an air-cooled, in-row coolant distribution unit suitable to dissipate heat generated by a plurality of rack-mounted servers.

FIG. 3 shows an isometric view from in front and to the side of an outlet-face of an air-cooled, in-row coolant distribution unit as in FIG. 2.

FIG. 4 shows a side elevation view of the outlet face of the air-cooled, in-row cooland distribution unit shown in FIG. 3.

FIG. 5 shows an isometric view of a v-shaped coil suitable for transferring heat from a liquid passing therethrough to a stream of gas, e.g., air, passing transversely through the coil, e.g., from the inlet face of the air-cooled, in-row coolant distribution unit to the outlet face thereof.

FIG. 6 schematically illustrates a plan view from above the air-cooled, in-row coolant distribution unit shown in FIG. 3. A V-shaped coil as shown in FIG. 5 is also visible.

FIG. 7 shows an isometric view from in front and to the side of an outlet-face of another air-cooled, in-row coolant distribution unit as in FIG. 2.

FIG. 8 shows a plan view from above the air-cooled, in-row coolant distribution unit shown in FIG. 7, with a cabinet door open.

FIG. 9 schematically illustrates a plan view from above the air-cooled, in-row coolant distribution unit shown in FIG. 7. A V-shaped coil as shown in FIG. 5 is also visible.

FIG. 10 schematically illustrates a plan view from above yet another air-cooled, in-row coolant distribution unit. In FIG. 10, the liquid-to-air heat exchanger is shown oriented at an angle across the coolant distribution unit and the fan is shown mounted externally relative to an outlet face.

FIG. 11 schematically illustrates a plan view from above still another air-cooled, in-row coolant distribution unit. In FIG. 11, the liquid-to-air heat exchanger is shown oriented at an angle across the coolant distribution unit and the fan is shown mounted internally relative to an outlet face.

FIG. 12 shows an isometric view from in front and to the side of an outlet-face of another air-cooled, in-row coolant distribution unit. In FIG. 12, the fans are mounted internally relative to the outlet face and the coil of is oriented within the coolant distribution unit such that air flows generally orthogonally relative to the coil as the air passes from the inlet face to the outlet face.

FIG. 13 shows an isometric view from in front and to the side of an inlet-face of the coolant distribution unit shown in FIG. 12.

FIG. 14 shows an isometric view of the coil (and its manifolds) from the coolant distribution unit shown in FIGS. 12 and 13.

FIG. 15 shows front and side elevation views of a radial or centrifugal blower as used by disclosed in-row coolant distribution units, e.g., as shown among the various embodiments briefly described above and in further detail below.

FIG. 16 shows a typical flow pattern of air through a blower of the type shown in FIG. 15.

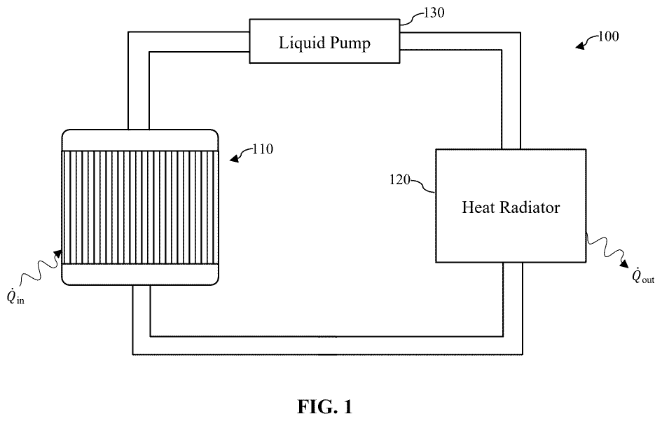

### DETAILED DESCRIPTION

The following describes various principles related to liquid-cooling systems for data centers. For example, certain aspects of disclosed principles pertain to coolant distribution units and, more particularly but not exclusively, to in-row coolant distribution units suitable to be installed within a row of server racks. That said, descriptions herein of specific apparatus configurations and combinations of method acts are but particular examples of contemplated systems chosen as being convenient illustrative examples of disclosed principles. One or more of the disclosed principles can be incorporated in various other systems to achieve any of a variety of corresponding system characteristics.

Thus, systems having attributes that are different from those specific examples discussed herein can embody one or more presently disclosed principles, and can be used in applications not described herein in detail. Accordingly, such alternative embodiments also fall within the scope of this disclosure.

As noted elsewhere herein, a data center can house any desired number of servers, each of which has a variety of heat-generating electronic components that need to be maintained at or below an upper temperature threshold. In some data centers, the servers are distributed among a plurality of racks and the racks are arranged throughout the data center in a desired fashion, often in rows of racks with aisles running between adjacent rows of racks. Conventional air-cooled data centers have typically had a “cold aisle” and each row of racks adjacent the cold aisle, e.g., on opposed sides of the cold aisle, has their inlet face oriented toward the cold aisle, allowing fresh, cool air to be drawn into the servers and across the heat-generating electrical components. The next aisle over from each cold aisle (in both lateral direction) is typically a “hot aisle” to which heated air exhausts from the adjacent racks. Thus, each row of racks adjacent the hot aisle, e.g., on opposed sides of the hot aisle, has their outlet, or exhaust, face oriented toward the hot aisle.

Such data center designs remain dominant across the industry. Disclosed in-row coolant distribution units, or CDUs, and related principles can deliver substantial cooling improvements over traditional air-cooling techniques while remaining compatible with existing, available data-center infrastructure. Thus, disclosed principles enable the use of much higher-performance servers, which generate substantially more heat, in conventional data centers than have previously been supported using conventional cooling systems. For example, a secondary flow network can distribute coolant among a group of servers (e.g., among servers mounted in one rack or across a plurality of racks). As the coolant passes through each server, it can absorb heat generated by one or more components therein. The heated coolant can be collected from each group of servers and passed through a coil as described more fully below in a disclosed, in-row coolant distribution unit. The coolant distribution unit, in turn, can direct one or more flows of air (or other gas), drawn from a cold aisle across a radiator coil (a liquid-to-air heat exchanger) within the coolant distribution unit. As the relatively cooler air (or other gas) passes through the coil, the coolant passing through the coil rejects the heat absorbed from the servers to the stream of air or other gas, which then is directed out of the in-row coolant distribution unit to the hot-aisle of the data center. In turn, the heated air delivered to the hot-aisle of the data center can be directed through, e.g., a cooling tower or other air-conditioning device to reject the heat to another environment, cooling the air, which can be delivered to the cold-aisles of the data center.

Some disclosed in-row coolant distribution units are so sized as to fit within the footprint of a commonly available server rack, e.g., a standard 42U rack. Some disclosed in-row coolant distribution units (CDUs) incorporate a centrifugal fan that provides high flow rates typically associated with axial fans and high pressure head typically associated with centrifugal blowers to ensure a high flow rate of cool air through the coils. In some embodiments, a disclosed array of 4 centrifugal blowers can drive between about 5,000 and about 7,500 cubic-feet-per-minute (cfm) (e.g., between about 5,500 cfm and about 7,000 cfm, or between about 6,000 cfm and about 7,000 cfm) of air through a single coil oriented substantially parallel to the inlet and outlet faces of the CDU.

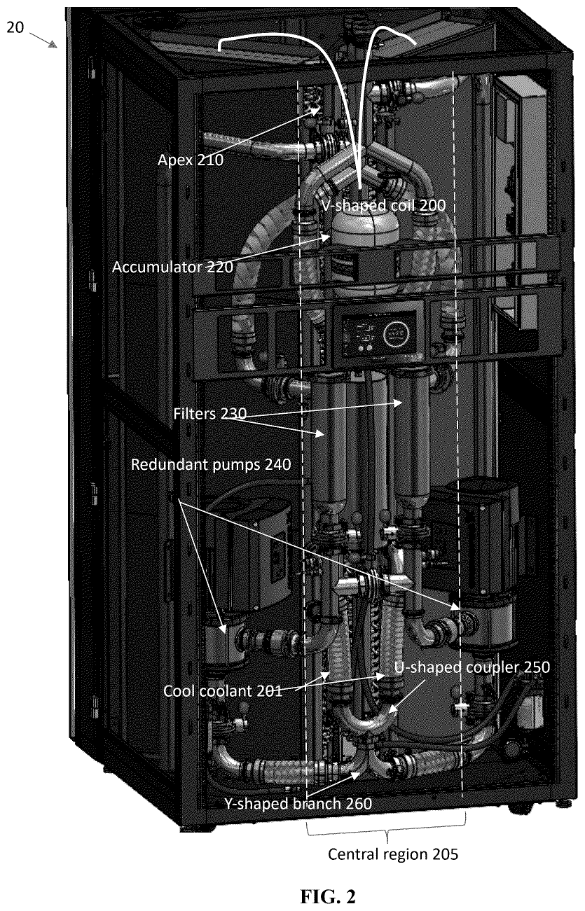

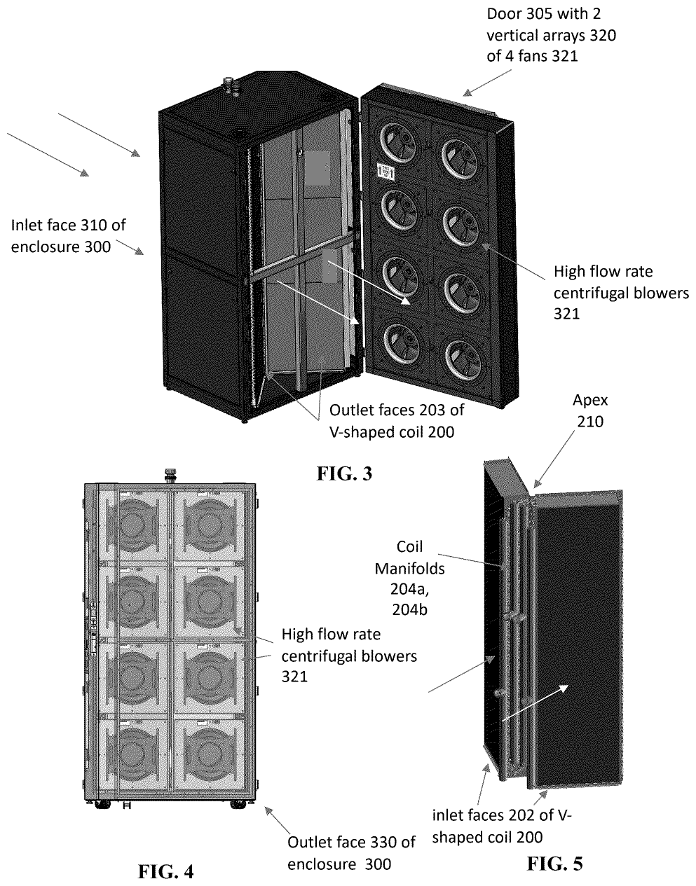

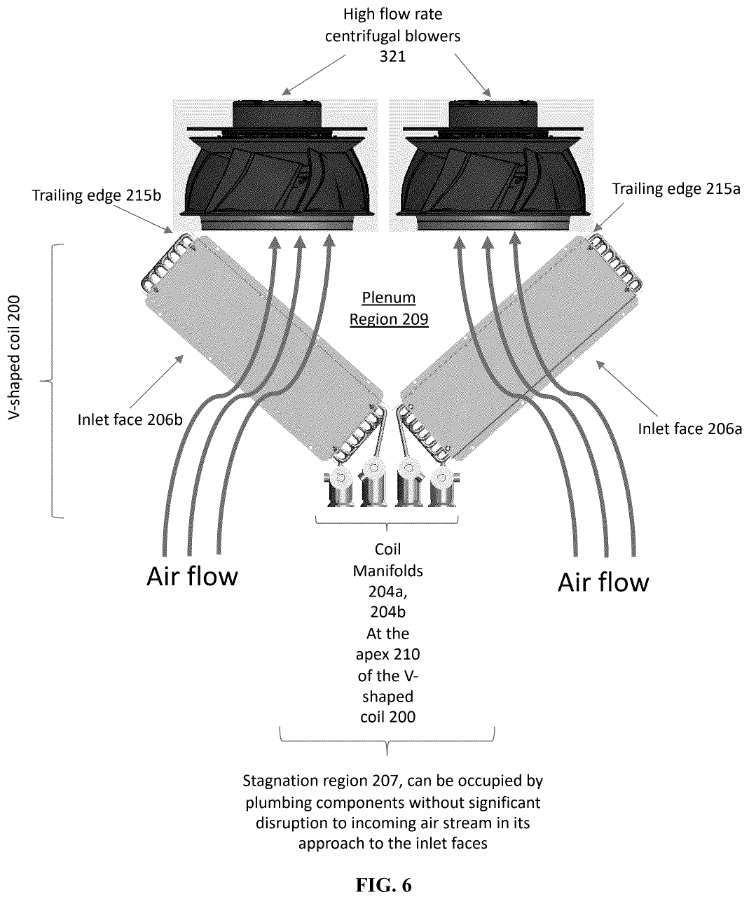

Referring now to FIG. 2, an embodiment of an in-row CDU 20 will be described. In FIG. 2, the outer covers of the top face and the inlet face 310 (FIG. 3) have been removed to reveal internal features of the CDU 20. A V-shaped coil 200 is shown positioned within an interior of the CDU chassis, e.g., in the background of FIG. 2, with the inlet faces 206a, 206b (FIG. 6) of the V-shaped coils visible. Nearer to the foreground, various liquid-plumbing components are visible. Of particular note, most of the major plumbing components (e.g., pipes, filters 230, conduits, controls and accumulators 220) are positioned vertically along a central region 205 of the CDU. For example, dividing the inlet face of the CDU 200 (which is visible in the foreground) into three, equally sized and vertically oriented regions (indicated by the vertical dashed lines), most of the plumbing features are positioned such that a majority portion of a projection of those features onto the inlet face 310 of the CDU falls within the center third of the inlet face, e.g., within the middle of the three, equally sized and vertically oriented regions. In FIG. 2, all major components except for the pumps 240 are positioned in the central region 205 of the CDU 200. For example, with a V-shaped coil 200, an apex 210 of the “V” can be positioned downstream (with respect to the flow of air passing through the CDU 200 from the cold aisle of the data center to the hot aisle of the data center) of the plumbing components. Since the apex 210 of the “V” would tend to be a point of stagnation (e.g., a region of little or no airflow), the stream of incoming cool air typically would split, with one subflow passing through one side of the V-shaped coil 200 and another subflow passing through the other side of the V-shaped coil.

By placing most of the plumbing components upstream of the apex 210 of the V-shaped coil, the plumbing components do not appreciably increase a loss of static pressure through the CDU compared to providing a uniform stream of air to the V-shaped coil. Accordingly, such an arrangement reduces or eliminates internal static pressure losses as the cool air approaches the V-shaped coil. Stated differently, most of the internal plumbing features are positioned so as not to obstruct or otherwise to interfere with an incoming flow of air that will pass through the V-shaped coil 200.

Moreover, the V-shaped coil 200 provides substantially more surface area (for a given coil thickness) available for heat transfer compared to a coil oriented parallel to the inlet face of the CDU (e.g., as in FIG. 13). The system in FIGS. 2 and 3 routes incoming warm coolant, which enters an upper region of the CDU, to a vertical coil manifold 204a, 204b that distributes the warm coolant vertically along the apex 210 of the V-shaped coil 200 (FIG. 5) to both sides of the V-shaped coil. After being cooled, the coolant exits from both sides of the V-shaped coil 200 in a lower region of the CDU 20. The two flows of cooled coolant from the sides of the V-shaped coil 200 recombine with each other in a U-shaped coupler 250. The combined flow again splits in the Y-shaped branch 260 into two flows. Each pump 240 inlet is coupled with one of the outlets from the Y-shaped branch 260. Each sub-flow of cool liquid exits the pumps 240 and flows back to the central region of the CDU 20 adjacent the apex 210 of the V-shaped coil 200 and flows through a respective filter 230. The flows exiting the filter 230 recombine with each other in an upper region of the CDU 20 and a pipe carries the high-pressure, filtered and cooled coolant out of the CDU 20 to one or more nearby cooling loads, e.g., IT racks, where a portion of the coolant can be distributed among a plurality of rack-mounted servers or other IT equipment. In parallel with the flow of cooled coolant, an accumulator 220 can be so positioned as to remove any entrained gases from the coolant. In some embodiments, the coolant can be pumped and/or filtered before being cooled by the V-shaped coil 200.

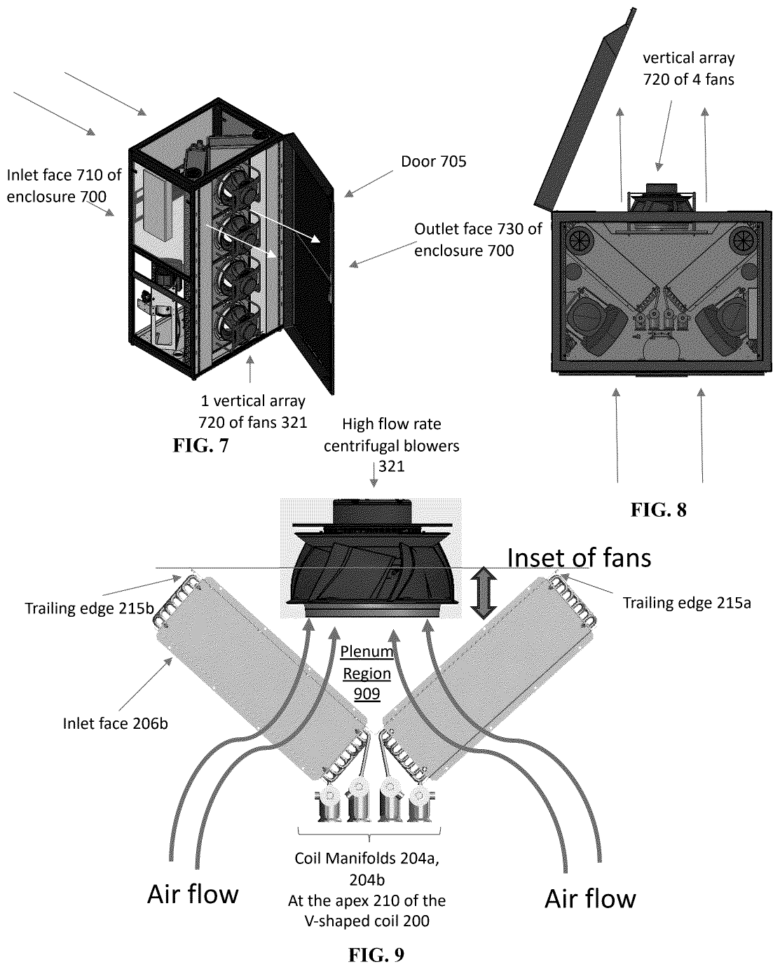

The open door 305 of the CDU shown in FIG. 3 reveals the outlet faces of the V-shaped coil. As FIG. 3 indicates, the interior region of the V-shaped coil (e.g., a region bounded by the outlet faces 203 of the V-shaped coil 200 and a plane, in this embodiment, spanning across the inlets to the blowers 321, defines a plenum 209 (FIG. 6) from which the array 320 of high-flow rate, centrifugal blowers 321 can draw air and to which the heated air passes from the outlet faces 203 of the V-shaped coil 200. In an embodiment as in FIG. 3, an array 320 of, for example in this embodiment, eight fans 321 can be mounted in a rear door 305 of the CDU. The door 305 can have a hinged connection with the CDU chassis, allowing the door 305 to swing outwardly about the hinge, which can provide convenient access to an interior of the CDU downstream of the V-shaped coil 200. As well, the fans 321 can be removably mounted to the door 305 such that one or more fans can be removed from the open door. For example, one or more of the fans 321 can be hot-swappable, e.g., can be removed and unplugged from the array 320 of, in this embodiment, eight fans 321. In some embodiments, a horizontal or a vertical array has two fans. An array chassis can mountably support the two fans, allowing the pair of fans to be installed in or on, or removed from, the door 305. A modular assembly having more than one fan 321 can increase the speed and efficiency of on-site installation and service of fans compared to prior CDUs. Such fans can be individually hot-swappable relative to the modular assembly or the modular assembly can be hot-swappable relative to the CDU, or both can be hot-swappable. The hinged door 305 can increase the ease and speed of service to the V-shaped coil 200, e.g., should the V-shaped coil need to be removed and replaced. Other embodiments have the array 720 of fans 321 mounted to the enclosure chassis, as in, for example, FIGS. 7 and 8. In such embodiments, the door 705 (FIG. 7) that provides an outlet face 730 of the enclosure 700 can open and close to provide access to the fans 321 but not necessarily to the V-shaped coil 200. Nevertheless, some embodiments that have fans mounted to the enclosure chassis 700 (FIG. 7) provide a slideable or a hinged connect of the fans to the enclosure chassis to provide access to the coil or plenum region 209 (FIG. 6).

The schematic illustration in FIG. 6 shows a relatively significant stagnation region 207 on an inlet side of the V-shaped coil 200, largely created by the manifolds 204a, 204b of the coil 200 that are positioned at the apex 210 of the V-shaped coil. Such a stagnation region 207 can accommodate plumbing components on the inlet side of the V-shaped coil 200, as noted above, without significantly disrupting the incoming flow of cooling air in its approach to the inlet faces 206a, 206b of the coil 200. Further, by arranging the plumbing components vertically within the vertical stagnation region 207, a technician can open a front face of the CDU (e.g., the face shown in the foreground of FIG. 2) to access the plumbing components. As shown in FIG. 6, the inlets to the fans/blowers 321 lie in a common plane (an “inlet plane”). In the CDU 20 of FIGS. 2 through 6, the inlet plane to the fans 321 is positioned downstream of the trailing edges 215a, 215b of the V-shaped coil 200.

The CDU depicted among FIGS. 7, 8, 9 and 10 differs from the CDU embodiment just described, despite sharing many similarities (e.g., a V-shaped coil 200, stagnation region 207 occupied by plumbing components). Perhaps most notably, the CDU shown in FIGS. 7-10 has one vertical array 720 of fans 321, compared to the pair of vertical arrays 320 of fans 321 shown in FIGS. 3 and 4. Although some CDU embodiments having a single array 720 of fans can position the inlet plane of the fans 321 adjacent or in the plane defined by the trailing edges 215a, 215b of the V-shaped coil 200 as with the two-array embodiment in FIG. 6, other single-fan-array embodiments position the inlet plane of the fan array 720 inboard of the trailing edges, as with the embodiment shown in FIG. 9. By positioning the fan inlets within the volume defined by an interior of the V-shaped coil 200, the CDU can be made shallower front-to-back (e.g., from the inlet face to the outlet face of the CDU). This can be helpful also or alternatively because the CDU can be made narrower, as by bringing the trailing edges 215a, 215b of the V-shaped coil 200 closer together, without requiring the CDU to grow deeper front-to-back. The inventors discovered that, despite cutting the number of fans by 50%, CDU performance (as measured by energy removed for a given temperature change at a given flow rate through the CDU) dropped by far less than 50%. Under some operating conditions, a single-array embodiment of a CDU provided about 80% as much heat removal as a two-array embodiment of the CDU.

The plumbing features for a CDU shown among FIGS. 3 to 9 can share similar or the same features as described above in connection with the embodiment shown in FIG. 2. For example, features can be positioned upstream of the apex 210 of a V-shaped coil 200, the flow routing through the system can be similar or the same, etc.

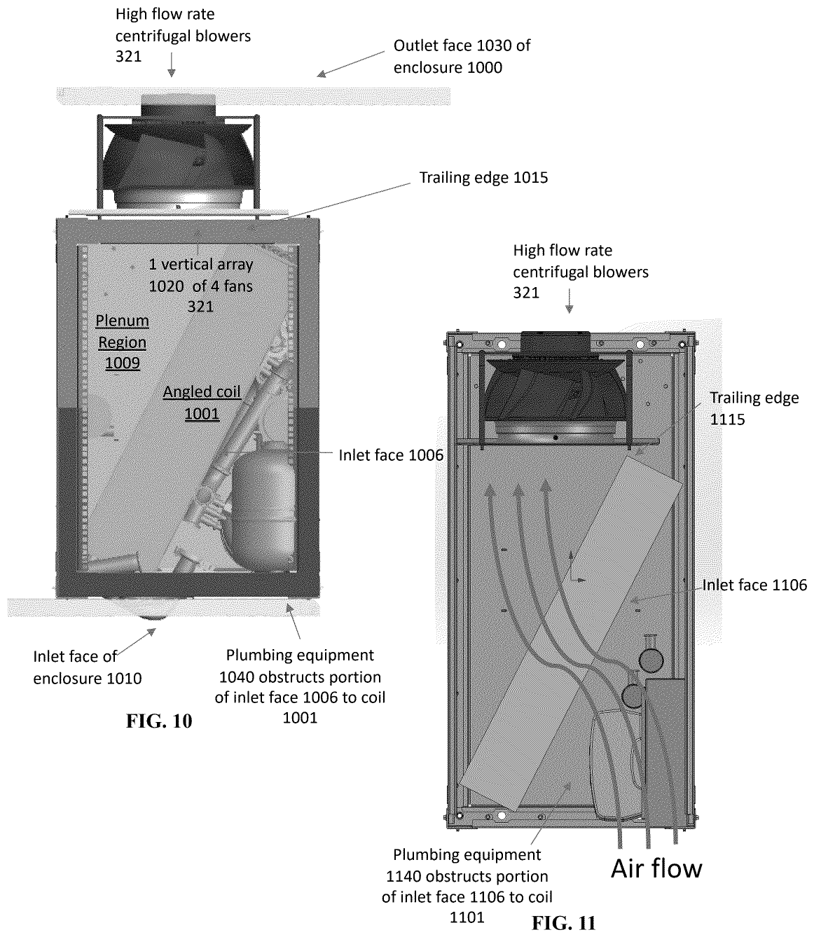

The CDU embodiments shown in FIGS. 10 and 11 incorporate a single, vertical array 1020 of fans 321 and an angled heat-exchanger coil 1001. The inlet plane of the fan array is positioned adjacent to or downstream of the trailing edge 1015 of the angled coil, allowing the coil to have as large a frontal inlet area 1006 as possible exposed to the airstream passing through the CDU within the internal constraints of the CDU, which are driven by the available depth and width of the CDU.

A CDU that incorporates a V-shaped coil has several advantages over a CDU that has an angled coil as in FIGS. 10 and 11. First, a V-shaped coil defines a plenum downstream of both sides of the coil and upstream of the fans, allowing a generally more uniform flow profile through each side of the V-shaped coil compared to the flow profile through the angled coil of FIGS. 10 and 11. Second, a V-shaped coil has an apex upstream of which components such as accumulators, filters, and other plumbing can be positioned while providing the same or more overall surface area as can be attained using an angled coil. Unlike a CDU having an angled coil, however, the plumbing components upstream of the apex of a V-shaped coil do not directly block, or shadow, an incoming stream of air passing through the coil. That is to say, plumbing and other components 1040 positioned upstream of an inlet face 1006 to an angled coil 1001 (or in the plenum region 1009) can disrupt an incoming stream of air, which may limit or reduce the rate or uniformity of air flow through the coil, which in turn can reduce the overall effectiveness of the coil. Similar disadvantages can accrue if plumbing or other components obstruct the flow through a V-shaped coil, but CDUs having a V-shaped coil have a central region, as described above, upstream of the apex where such obstructions are less important or significant to coil performance.

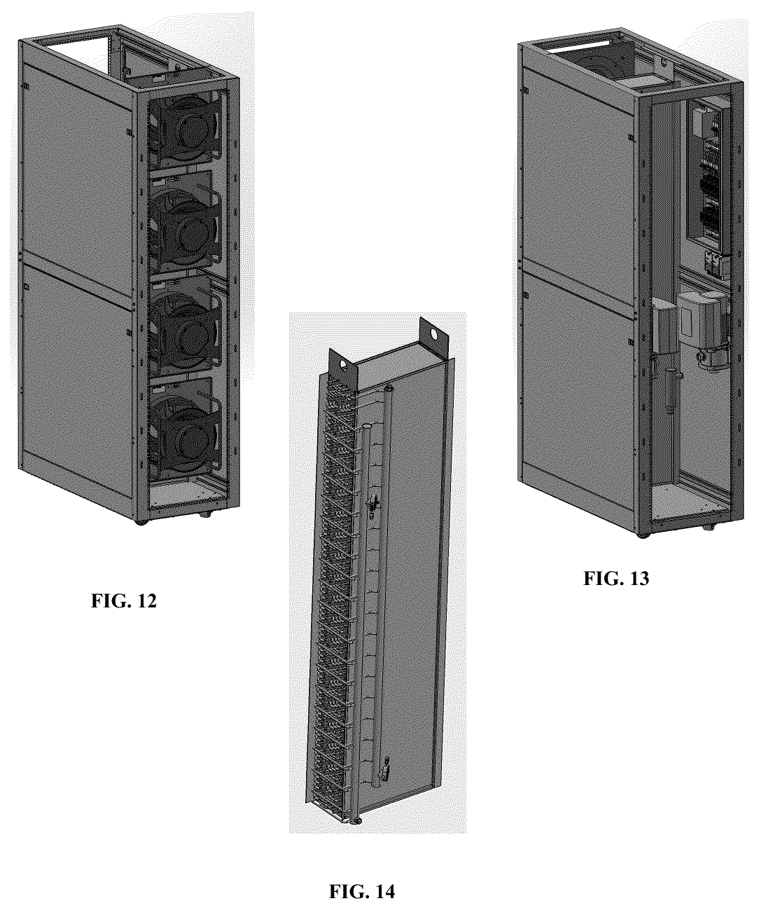

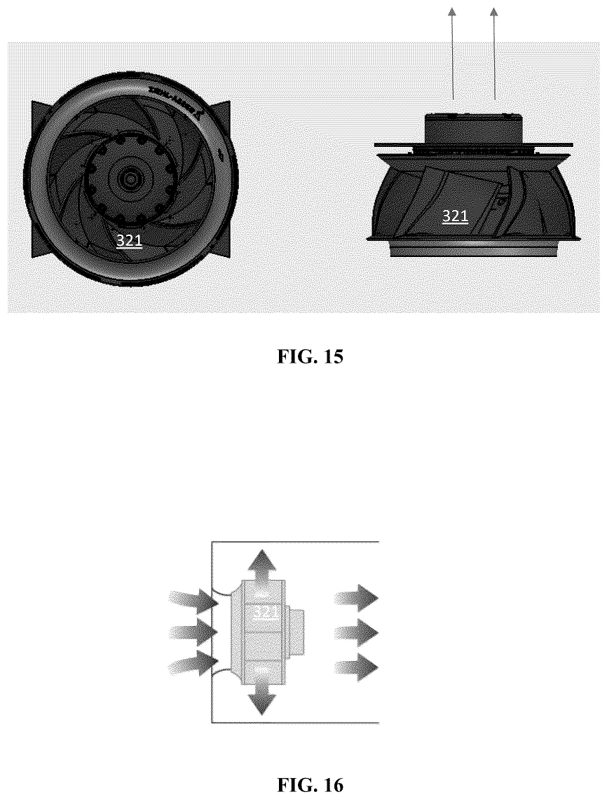

FIGS. 12, 13 and 14 show yet another CDU embodiment with a flat, or transverse, coil. The embodiment shown in these drawings orients the coil (FIG. 14) laterally across, e.g., orthogonal across, the CDU. With this embodiment, the CDU can be shallower than with an angled coil or a V-shaped coil. Nevertheless, if a CDU is expected to be used within a row of IT racks, a shallower CDU does little benefit since the adjacent IT racks can and likely will be deeper. Although plumbing components in a CDU as in FIGS. 12, 13 and 14 can be spaced from the inlet to the flat coil and thereby airflow obstructions can be reduced compared to an angled coil embodiment, substantial interior volume of the CDU can be wasted (e.g., left unoccupied and thus unused for cooling or other purposes). In some flat coil embodiments, a plurality of coils can be placed front to back, typically with a plenum space between adjacent coils. Such embodiments can be useful to provide additional heat-transfer area using flat coils. However, the stream of air increases in temperature as it passes through each coil stage, reducing the effectiveness of heat transfer from successive downstream coils and the overall efficiency of the CDU compared to a CDU having a V-shaped coil that provides equivalent surface area using a single stage coil.

Other CDU embodiments can incorporate three or more vertical arrays of such fans. And, each vertical array of fans can have more or fewer than four fans 321, whether a CDU has a single array 720 of fans as in FIGS. 7-10, a pair of arrays 320 as in FIGS. 3 and 4, or three or more arrays of fans. For example, in some embodiments, each array of fans 320, 720 for a CDU can have 2 fans, 3 fans, 4 fans, 5 fans, 6 fans, or more. And, each such array of fans can be oriented vertically as shown in FIGS. 3, 5, 7, 8, 9 and 10, or each array of fans can be oriented horizontally. Further, a vertical or a horizontal array of fans can include one or more fan modules. For example, to facilitate servicing, installation, removal and repair, two or more fans may be combined into a single fan module. Such a fan module can include a frame or chassis to which the fans of the module are mounted. Each such fan module can be installed in a CDU, allowing a plurality of fans to be installed, serviced, removed, or repaired concurrently by the insertion or removal of the fan module.

The previous description is provided to enable a person skilled in the art to make or use the disclosed principles. Embodiments other than those described above in detail are contemplated based on the principles disclosed herein, together with any attendant changes in configurations of the respective apparatus or changes in order of method acts described herein, without departing from the disclosed principles. Various modifications to the examples described herein will be readily apparent to those skilled in the art.

For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of in-row heat exchangers that can be devised using the various concepts described herein.

Moreover, nothing disclosed herein is intended to be dedicated to the public regardless of whether such disclosure is explicitly recited in the claims. No claim feature is to be construed under the provisions of 35 USC 112 (f), unless the feature is expressly recited using the phrase “means for” or “step for”.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by reference in its entirety for all purposes.

The appended claims are not intended to be limited to the embodiments shown herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

1. A coolant distribution unit, comprising:
an enclosure defining an inlet face and an outlet face;
a V-shaped coil positioned in the enclosure between the inlet face and the outlet face, wherein the V-shaped coil defines an apex and a pair of trailing edges positioned downstream of the apex, wherein the apex is positioned between the trailing edges and the inlet face of the enclosure, wherein the trailing edges are positioned between the apex and the outlet face of the enclosure;
an array of fans configured to draw air through the V-shaped coil and to exhaust the air from the enclosure; and
a hot-coolant inlet, wherein the V-shaped coil is configured to transfer heat from the coolant received at the hot-coolant inlet to the air drawn through the V-shaped coil.

2. The coolant distribution unit according to claim 1, further comprising a selected one or more of a filter, a pipe, a pump, and an accumulator positioned between the apex of the V-shaped coil and the inlet face of the enclosure.

3. The coolant distribution unit according to claim 1, further comprising a cool-coolant outlet and an arrangement of plumbing configured to convey coolant from the V-shaped coil to the cool-coolant outlet after the coolant has passed through the V-shaped coil.

4. The coolant distribution unit according to claim 1, wherein the array of fans comprises a vertical array of fans.

5. The coolant distribution unit according to claim 4, wherein the vertical array of fans is a first vertical array of fans, the coolant distribution unit further comprising a second vertical array of fans positioned laterally adjacent the first vertical array of fans.

6. The coolant distribution unit according to claim 4, wherein the vertical array of fans comprises a plurality of fans, each having an inlet, wherein the plurality of fan inlets are substantially coplanar with each other.

7. The coolant distribution unit according to claim 6, wherein the plurality of fan inlets is positioned between the apex and the trailing edges of the V-shaped coil.

8. An in-row coolant distribution unit, comprising:
a cabinet defining a first major face and a second major face;
a V-shaped coil positioned in the cabinet between the first major face and the second major face, the V-shaped coil having an apex and a corresponding pair of trailing edges positioned laterally outward of the apex, the V-shaped coil further defining a respective heat-transfer region between the apex and each of the pair of trailing edges;
a liquid inlet and a vertical coil manifold adjacent the apex of the V-shaped coil, the vertical coil manifold coupled with the liquid inlet and being configured to distribute a liquid received through the inlet vertically along the V-shaped coil to each respective heat-transfer region between the apex and each of the pair of trailing edges;
an array of fans configured to draw air through each respective heat-transfer region between the apex and each of the pair of trailing edges and to exhaust the air from the cabinet after the air passes through the V-shaped coil.

9. The in-row coolant distribution unit according to claim 8, wherein each fan in the array of fans has an inlet face, wherein the inlet face of at least one fan in the array of fans is positioned between a plane defined by the trailing edges of the V-shaped coil and the apex of the V-shaped coil.

10. The in-row coolant distribution unit according to claim 8, further comprising:
a liquid outlet; and
an arrangement of plumbing configured to collect the liquid vertically distributed along the V-shaped coil after the liquid has passed through each respective heat-transfer region of the V-shaped coil and to convey the collected liquid to the liquid outlet.

11. The in-row coolant distribution unit according to claim 8, further comprising an accumulator positioned between the apex of the V-shaped coil and the first major face of the cabinet.

12. The in-row coolant distribution unit according to claim 8, wherein the array of fans comprises a vertical array of fans.

13. The in-row coolant distribution unit according to claim 12, wherein the vertical array of fans is a first vertical array of fans, the coolant distribution unit further comprising a second vertical array of fans positioned laterally adjacent the first vertical array of fans.

14. The in-row coolant distribution unit according to claim 8, wherein the vertical coil manifold comprises a first vertical manifold configured to distribute the liquid along one of the pair of heat transfer regions, wherein the vertical coil manifold comprises a second vertical manifold configured to distribute the liquid along the other one of the pair of heat transfer regions.

15. The in-row coolant distribution unit according to claim 8, further comprising a coupler configured to recombine a flow of liquid from one of the pair of heat transfer regions with a flow of liquid from the other one of the pair of heat transfer regions.

16. The in-row coolant distribution unit according to claim 8, further comprising at least one pump configured to pump the liquid after the liquid passes through the V-shaped coil.

17. The in-row coolant distribution unit according to claim 8, further comprising at least one pump configured to pump the liquid before the liquid passes through the V-shaped coil.

18. The in-row coolant distribution unit according to claim 8, wherein the array of fans is further configured to draw air through the first major face of the cabinet before the air passes through each respective heat-transfer region of the V-shaped coil.

19. The in-row coolant distribution unit according to claim 18, wherein the array of fans is further configured to exhaust the air through the second major face of the cabinet.
